(19) United States
(12) Patent Application Publication
(10) Pub. No.: US 2026/0215122 A1
(43) Pub. Date: Jul. 23, 2026

(54) Display Panel and Vehicle

(71) Applicant: LG Display Co., Ltd., Seoul (KR)

(72) Inventors: Min Gue Shin, Paju-si (KR); Seung Kwang Roh, Paju-si (KR); Woo Chul Choi, Paju-si (KR); Sang Kyoung Moon, Paju-si (KR); Dong Il Choi, Paju-si (KR); Jung Mo Cho, Paju-si (KR); Chi Hak Lee, Paju-si (KR); Bo A. Jin, Paju-si (KR)

(21) Appl. No.: 19/441,075

(22) Filed: Jan. 6, 2026

(30) Foreign Application Priority Data
Jan. 23, 2025 (KR) 10-2025-0010303

(51) Int. Cl. H10K 59/38; H10K 59/35; H10K 59/40; H10K 59/80

(52) U.S. Cl. CPC H10K 59/38; H10K 59/35; H10K 59/40; H10K 59/879

(57) ABSTRACT

Disclosed is a display panel. The display panel includes a first subpixel having a first light-emitting element configured to emit a first color light, a second subpixel having a second light-emitting element configured to emit a second color light, a first lens disposed on the first subpixel to overlap with the first subpixel, and a second lens disposed on the second subpixel to overlap with the second subpixel, and the first and second lenses include a second color reduction color filter pigment configured to reduce a luminance of the second color light.

### CROSS-REFERENCE TO RELATED APPLICATIONS

This application claims the priority under 35 U.S.C. § 119 (a) to the Republic of Korea Patent Application No. 10-2025-0010303, filed on Jan. 23, 2025, the entire contents of which are hereby expressly incorporated by reference into the present application.

### TECHNICAL FIELD

The present disclosure relates to a display panel and a vehicle.

### BACKGROUND

As information technology develops, the market for display devices, which are a connection medium between users and information, is growing. Accordingly, display devices, such as light-emitting diode (LED) displays, quantum dot displays (QDDs), and liquid crystal displays (LCDs), are increasingly used.

Recently, as the above-described display devices are used in vehicles, various technologies, such as a light control film (LCF) using a louver and an LCF in panel (LCP) that embeds lenses within a panel, are being used to block light from the display devices so as not to obstruct the driver's view.

The description provided in the background section should not be assumed to be prior art merely because it is mentioned in or associated with the background section. The background section may include information that describes one or more aspects of the subject technology.

### SUMMARY

However, the inventors of the present application found that, the LCF has a problem of reducing front brightness by 20-30%, and the LIP improves front brightness through light collection by the lens but causes a red peak in which the luminance of red light becomes excessive when driven at low gray levels due to the lateral leakage current of a light-emitting element, thus resulting in a color difference.

Accordingly, the present disclosure is directed to a display panel that substantially obviates one or more problems due to limitations and disadvantages of the related art.

An object of the present disclosure is to provide a display panel capable of improving a low gray-level color defect and luminosity efficiency shift that occurs when front brightness increases due to light collection by lenses.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the disclosure, as embodied and broadly described herein, a display panel includes a first subpixel having a first light-emitting element configured to emit a first color light, a second subpixel having a second light-emitting element configured to emit a second color light, a first lens disposed on the first subpixel to overlap with the first subpixel, and a second lens disposed on the second subpixel to overlap with the second subpixel, wherein the first and second lenses include a second color reduction color filter pigment configured to reduce a luminance of the second color light.

An amount of reduction in the luminance of the second color light by the second color reduction color filter pigment may be greater than an amount of reduction in a luminance of the first color light by the second color reduction color filter pigment.

Each of the first and second light-emitting elements may include a first electrode conductively connected to a driving transistor of a corresponding one of the first and second subpixels, an emission layer disposed on the first electrode, and a second electrode disposed on the emission layer, and the emission layer of the first light-emitting element and the emission layer of the second light-emitting element may be conductively connected to each other.

An emission voltage may be applied to the first electrode of the first light-emitting element, the emission layer of the first light-emitting element may emit the first color light with a first luminance, and the emission layer of the second light-emitting element may emit the second color light with a second luminance lower than the first luminance due to a lateral leakage current through the emission layer of the second light-emitting element.

The first luminance of the first color light passing through the second color reduction color filter pigment comprised in the first lens may be maintained, and the second luminance of the second color light may be reduced by the second color reduction color filter pigment included in the second lens.

The first color light may be green light or blue light, and the second color light may be red light.

The second color reduction color filter pigment may include at least one of diketopyrrolopyrrole (DPP), quinacridone, or perylene red, as a pigment for red color filters.

The first and second lenses may include the second color reduction color filter pigment in a range of 0.01 wt % to 1 wt %.

A number of the first lens disposed on the first light-emitting element may be one, and a number of the second lens disposed on the second light-emitting element may be one.

The display panel may further include an encapsulation layer disposed on the first and second light-emitting elements, an optical layer disposed between the encapsulation layer and the first and second lenses, and a low refractive index film disposed on the first and second lenses, and a refractive index of the first and second lenses may be greater than a refractive index of the low refractive index film.

A thickness of the optical layer may be less than a maximum height of each of the first and second lenses. A thickness of the low refractive index film may be greater than a maximum height of each of the first and second lenses.

The display panel may further include a bank configured to define an emission area of the first subpixel and an emission area of the second subpixel, and the bank may overlap with a space between the first lens and the second lens.

The display panel may further include a first barrier positioned between the encapsulation layer and the optical layer, the first barrier overlaps with the bank, and the first barrier may be a black matrix including a light-absorbing material.

The display panel may further include a second barrier between the optical layer and the low refractive index film, the second barrier overlaps with the bank, and the second barrier may be used as touch electrodes formed of a metallic material.

An edge of the second barrier may overlap with edges of the first and second lenses.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a diagram illustrating the concept of the configuration of a display device of the present disclosure.

FIG. 2 is a circuit diagram illustrating an example of an equivalent circuit of a subpixel applicable to a display panel of the present disclosure.

FIG. 3 is a cross-sectional view illustrating an example of a cross-sectional structure applied to the display panel of the present disclosure.

FIG. 4 is a cross-sectional view illustrating the flow of a lateral leakage current through an emission layer in the display panel shown in FIG. 3.

FIG. 5 is a cross-sectional view illustrating an example of the detailed cross-sections of first and second light-emitting elements shown in FIG. 3 to explain the flow of the lateral leakage current through the emission layer in more detail;

FIG. 6 is a diagram illustrating optical spectral characteristics to explain the luminance of a second color light when a plurality of lenses shown in FIG. 3 does not include a second color reduction color filter pigment.

FIG. 7A is a diagram comparatively illustrating light having a color from each subpixel by comparing a case in which the plurality of lenses does not include the second color reduction color filter pigment and a case in which the plurality of lenses includes the second color reduction color filter pigment.

FIG. 7B is a diagram comparatively illustrating light having a color from each subpixel by comparing a case in which the plurality of lenses does not include the second color reduction color filter pigment and a case in which the plurality of lenses includes the second color reduction color filter pigment.

FIG. 8A is a diagram illustrating luminous efficacies of first, second, and third subpixels and colors on a display screen in the case in which the plurality of lenses does not include the second color reduction color filter pigment and the case in which the plurality of lenses includes the second color reduction color filter pigment.

FIG. 8B is a diagram illustrating luminous efficacies of first, second, and third subpixels and colors on a display screen in the case in which the plurality of lenses does not include the second color reduction color filter pigment and the case in which the plurality of lenses includes the second color reduction color filter pigment.

FIG. 9 is a simulation graph illustrating color differences of the display panel according to an exemplary embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Hereinafter, exemplary embodiments will be described with reference to the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure, and implementation methods thereof will be clarified through following example embodiments described with reference to the accompanying drawings. The present disclosure may, however, be embodied in different forms and should not be construed as limited to example embodiments set forth herein. Rather, these example embodiments may be provided so that this disclosure may be sufficiently thorough and complete to assist those skilled in the art to fully understand the scope of the present disclosure. Further, the present disclosure is only defined by scopes of claims.

The shapes (e.g., sizes, lengths, widths, heights, thicknesses, locations, radii, diameters, and areas), ratios, angles, numbers, and the like, which are illustrated in the drawings to describe various example embodiments of the present disclosure are merely given by way of example. Therefore, the present disclosure is not limited to the illustrations in the drawings.

The same reference numerals or symbols in different drawings indicate similar or identical components. In addition, some of the drawings may be exaggerated for effective explanation of the thicknesses, ratios, and dimensions of components. Components illustrated in the drawings may have a different scale from the actual scale for convenience of explanation, and are not limited to the scale illustrated in the drawings.

In construing an element, the element is construed as including an error range or tolerance range although there is no explicit description of such an error or tolerance range.

In the following description, when a component (region, layer, part, or the like) is referred to as being “on,” “connected to,” or “coupled to” another component, it may be directly on, connected to, or coupled to the other component, or intervening components may be present.

In describing a time relationship, for example, when the temporal order is described as, for example, “after,” “subsequent,” “next,” and “before,” a case which is not continuous may be included unless a more limiting term, such as “just,” “immediate(ly),” or “direct(ly)” is used.

As used herein, the term “and/or” includes any and all combinations of one or more of the associated listed items. The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

Terms, such as “first,” “second,” “A,” “B,” “(a),” and “(b)” and the like, are used to describe various components, and these components should not be construed as being limited by these terms. These terms are used only to distinguish one component from other components. For example, a first component described hereinafter may be termed a second component, and similarly, a second element described hereinafter may be termed as a first component, without departing from the scope of the disclosure. Singular expressions may encompass plural expressions, unless they have clearly different contextual meanings.

Terms, such as “below,” “under,” “above,” “on,” and the like, may be used to describe the relationship between components illustrated in the drawings. The terms are relative concepts, and are described based on the orientation illustrated in the drawings. For example, one or more other parts may be located between two parts unless “directly” or “immediately” is used. Spatially relative terms, such as “below,” “beneath,” “lower,” “above,” “upper,” and the like, may be used herein for ease of description to describe a relationship between one element or component and another element or component as illustrated in the drawings. For example, “below” or “lower” with respect to a first component may be in the opposite direction to “above” or “upper” with respect to the first component.

It will be understood that the spatially relative terms may encompass different orientations of an element in use or operation in addition to the orientation depicted in the figures. For example, if a device in one of the figures is turned over, elements described as “below” or “beneath” other elements would then be oriented “above” the other elements. Thus, the exemplary term “below” may encompass both an orientation of below and above.

The terms “comprises,” “comprising,” “including,” and “having” are inclusive and therefore specify the presence of stated features, integers, steps, operations, elements, components, and/or combinations thereof, but do not preclude the possibility the presence or addition of one or more other features, integers, steps, operations, elements, components, and/or combinations thereof.

Individual features of various embodiments in the following description may be partially or wholly coupled to or combined with each other, and may be technically interconnected and operated in various ways, and the respective embodiments may be implemented independently of each other or implemented together in a related manner.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, a display device of the present disclosure will be described with reference to the accompanying drawings and exemplary embodiments.

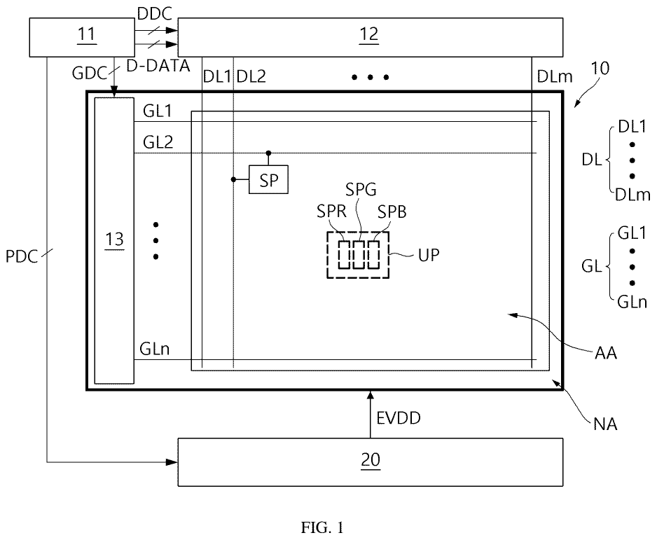

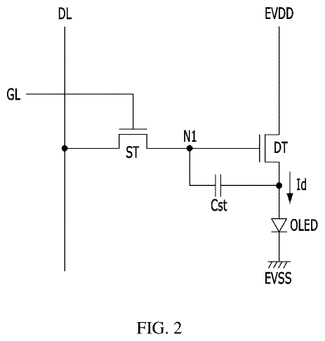

FIG. 1 is a diagram illustrating the concept of the configuration of the display device according to an exemplary embodiment of the present disclosure, and FIG. 2 is a circuit diagram illustrating an example of an equivalent circuit of a subpixel applicable to a display panel according to an exemplary embodiment of the present disclosure.

As shown in FIG. 1, the display device 1 according to one exemplary embodiment of the present disclosure may include a display panel 10, a timing controller 11, a data driver 12, a gate driver 13, and a power supply 20.

FIG. 1 illustrates a case in which the timing controller 11, the data driver 12, and the power supply 20 are provided separately as an example, but, unlike FIG. 1, the timing controller 11, the data driver 12, and the power supply 20 may be integrated in whole or in part within a drive integrated circuit. In FIG. 1, the data driver 12, the gate driver 13, and the power supply 20 may compose a panel driving circuit to drive the display panel 10.

As shown in FIG. 1, the gate driver 13 may be provided in a non-active area NA of the display panel 10, and may be formed directly on a substrate of the display panel 10 in a Gate driver In Panel (GIP) manner. However, FIG. 1 is an example, and the gate driver 13 of the present disclosure is not limited to FIG. 1. As an example, the gate driver 13 may be connected to the display panel 10 using a tape automated bonding (TAB) method, a chip-on-glass (COG) or chip-on-panel (COP) method, or may be implemented using a chip-on-film (COF) method and connected to the display panel 10, without being limited thereto.

The display panel 10 may include an active area AA and the non-active area NA.

The active area AA may be an area where an image is displayed. A plurality of subpixels SP may be disposed in the active area AA, and an image may be displayed using the plurality of subpixels SP. An area where the plurality of subpixels SP is disposed may serve as the active area AA, and the non-active area NA may be an area that is located at the outer edge of the display panel 10 to fully or partially surround the active area AA, and where an image is not displayed. As an example, at least a portion or the entirety of the non-active area NA may be invisible from a front side of the display panel 10, for example, by being bent toward a rear side of the display panel 10, without being limited thereto. As another example, the entire non-active area NA may be flat.

The plurality of subpixels SP may be disposed in the active area AA. The plurality of subpixels SP may include first subpixels SPB that emit a first color light, second subpixels SPR that emit a second color light, and third subpixels SPG that emit a third color light. For example, the first color may be blue (B), the second color may be red (R), and the third color may be green (G). Embodiments are not limited thereto. As an example, a subpixel that emits light of a color other than red, green, and blue, such as white, cyan, yellow and magenta, etc. may be additionally or alternatively included.

The following exemplary embodiments will describe a case in which the plurality of subpixels SP emits light having different colors, such as red (R), green (G), or blue (B), as an example.

The plurality of subpixels SP emitting light having different colors may be grouped into one unit pixel UP.

When defining a pixel group for color expression as a unit pixel UP, the unit pixel UP may be configured to include, for example, a plurality of subpixels SPB, SPR, and SPG that emit red (R) light, green (G) light, and blue (B) light, or may further include a subpixel that emits white (W) light in addition to red (R) light, green (G) light, and blue (B) light. Each unit pixel UP may express various colors by mixing light having different colors emitted by the plurality of subpixels SP.

In FIG. 1, a case in which the unit pixel UP includes the red subpixel SPR that emits red (R) light, the green subpixel SPG that emits green (G) light, and the blue subpixel SPB that emits blue (B) light is illustrated as an example. Hereinafter, a case in which the first subpixel is the blue subpixel SPB, the second subpixel is the red subpixel SPR, and the third subpixel is the green subpixel SPG will be described as an example.

As an example, at least one panel driving circuit to drive the plurality of subpixels SP may be disposed in the non-active area NA or connected to the non-active area NA.

The timing controller 11 may supply digital image data D-DATA transmitted from a host system (not shown) to the data driver 12.

The timing controller 11 may receive timing signals, such as a vertical synchronization signal, a horizontal synchronization signal, a data enable signal, and a dot clock signal, from the host system and generate timing control signals for controlling the operation timing of the panel driving circuit.

The timing control signals may include a gate timing control signal GDC for controlling the operation timing of the gate driver 13, a data timing control signal DDC for controlling the operation timing of the data driver 12, and a power timing control signal PDC for controlling the operation timing of the power supply 20.

The data driver 12 is a component which supplies a data voltage to the plurality of pixels PX disposed in the active area AA. The data driver 12 may be configured in a form of an IC chip and thus, may also be referred to as a data integrated circuit D-IC. The data driver 12 may be connected to the plurality of subpixels SP through data lines DL: DL1 to DLm. The data driver 12 may generate data voltages, which are analog signals required to drive the plurality of subpixels SP, based on the digital image data D-DATA input from the timing controller 11, and supply the data voltages to the data lines DL. Although not shown in FIG. 1, the data driver 12 may be mounted in a chip on board (COB) manner, or in a method such as a chip on film (COF) method, a chip on glass (COG) method, a tape carrier package (TCP) method, or the like, and the present disclosure is not limited thereto.

The data driver 12 may convert the digital image data D-DATA into parallel data by performing data sampling and latch based on the digital image data D-DATA and the data timing control signal DDC input from the timing controller 11.

Thereafter, the data driver 12 may convert the digital image data D-DATA into analog data voltages depending on gamma compensation voltages in a digital-to-analog converter (hereinafter, DAC), and supply the analog data voltages to the plurality of subpixels SP through the data lines DL. The analog data voltages may be analog voltage values of different voltage levels so as to correspond to image gray levels to be expressed by the plurality of subpixels SP.

The data driver 12 may output the data voltages Vdata to the plurality of subpixels SP depending on the data timing control signal DDC. The data driver 12 may include a plurality of source driver integrated circuits. As an example, the source driver integrated circuit may include a shift register, a latch, a level shifter, a DAC, and an output buffer, without being limited thereto.

The gate driver 13 may generate scan signals SC based on the gate timing control signal GDC and supply the scan signals SC to the plurality of subpixels SP through gate lines GL: GL1 to GLn.

The power supply 20 may process input power depending on the power timing control signal PDC to generate a high-potential driving voltage EVDD with a fixed potential and supply the high-potential driving voltage EVDD to the display panel 10.

At least one subpixel SP among the plurality of subpixels SP may include, for example, a switching transistor ST, a driving transistor DT, a capacitor Cst, and a light-emitting element OLED, as shown in FIG. 2.

A first electrode of the switching transistor ST may be conductively connected to the data line DL to receive a data voltage, a second electrode of the switching transistor ST may be conductively connected to a first node N1, and a gate electrode of the switching transistor ST may be conductively connected to the gate line GL to receive a scan signal. The switching transistor ST may transmit the data voltage supplied through the data line DL to the first node N1 in response to the scan signal supplied through the gate line GL.

A first electrode of the driving transistor DT may receive a high-potential driving voltage EVDD, and a second electrode of the driving transistor DT may be conductively connected to a first electrode of the light-emitting element OLED. The driving transistor DT may generate a driving current Id flowing to the light-emitting element OLED in response to a voltage applied to a gate electrode of the driving transistor DT from the first node N1.

The capacitor Cst may have one end conductively connected to the first node N1 and the other end conductively connected to the second electrode of the driving transistor DT, and charge the first node N1 with a voltage applied thereto.

The light-emitting element OLED may output light corresponding to the driving current Id. The light-emitting element OLED may emit light having one color among red (R), green (G), blue (B), and white (W), without being limited thereto.

For example, the light-emitting element OLED may have an emission layer that generates light having one color. The emission layer may be implemented to emit light having a different color for each subpixel SP, such as white (W), red (R), green (G), or blue (B).

In addition, although not shown in FIG. 2, a compensation circuit (not shown) for compensating for the threshold voltage of the driving transistor DT may be further provided within the subpixel SP. The compensation circuit may include at least one transistor connected to the driving transistor DT and may be provided within the subpixel SP. Embodiments are not limited thereto. As an example, one or more transistors or one or more capacitors may be further included. As an example, the circuit configuration of the subpixel may be changed in various ways, without being limited to that shown in FIG. 2.

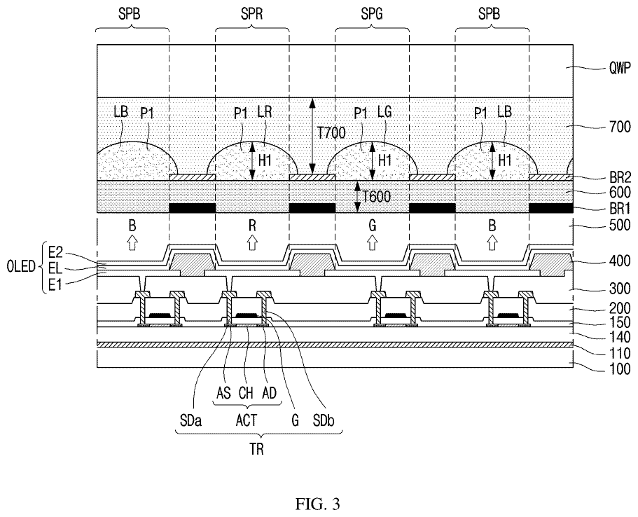

FIG. 3 is a cross-sectional view illustrating an example of a cross-sectional structure applied to the display panel according to an exemplary embodiment of the present disclosure.

As shown in FIG. 3, the display panel 10 may include a substrate 100, an insulating film 110, a buffer layer 140, a gate insulating film 150, an interlayer insulating film 200, a planarization film 300, a bank 400, and light-emitting elements OLED, an encapsulation layer 500, a first barrier BR1, an optical layer 600, a second barrier BR2, a plurality of lenses LB, LR, and LG, a low refractive index film 700, and a quarter wave plate QWP. Embodiments are not limited thereto. As an example, at least one of the above-mentioned components may be omitted, and/or at least one additional component may be further included.

In FIG. 3, the transistor TR may be one of the switching transistor ST or the driving transistor DT, and FIG. 3 shows a case in which the transistor TR is the driving transistor DT shown in FIG. 2, as an example. The cross-sectional structure of the display device in FIG. 3 is an example for understanding the present disclosure, and the present disclosure is not limited thereto.

As an example, the substrate 100 may be formed of a flexible plastic material to have flexibility, or may include a thin glass material having flexibility. As an example, the flexible plastic material may include polyethylene terephthalate (PET), polycarbonate (PC), acrylonitrile-butadiene-styrene copolymer (ABS), polymethyl methacrylate (PMMA), polyimide (PI), etc. Embodiments are not limited thereto. As an example, the substrate 100 may also be formed of a rigid material.

The insulating film 110 may be disposed on the active area AA and the non-active area NA on the substrate 100. The insulating film 110 may be disposed on the substrate 100 and protect structures on the substrate 100, which are vulnerable to moisture penetration, from moisture penetrating through the substrate 100. The insulating film 110 may include at least one inorganic film selected from among a silicon oxide (SiOₓ) film, a silicon nitride (SiNₓ) film, and a silicon oxynitride (SiOₓN_{y}) film, without being limited thereto. As an example, the insulating film 110 may be omitted depending on the design.

The buffer layer 140 may be provided on the insulating film 110. The buffer layer 140 may include an inorganic insulating material, such as silicon oxide (SiO) or silicon nitride (SiN), without being limited thereto.

The transistor TR may be disposed on the buffer layer 140. The transistor TR may include a gate electrode G, an active layer ACT, a source electrode SDa, and a drain electrode SDb.

The active layer ACT may include a source region AS, a channel region CH, and a drain region AD. The source region AS and the drain region AD have higher electrical conductivity than the channel region CH, and the channel region CH may form a channel in response to a voltage applied to the gate electrode G.

The gate insulating film 150 may be stacked on the buffer layer 140 while covering the active layer ACT. The gate insulating film 150 may insulate between the gate electrode G and the active layer ACT of the transistor TR.

The interlayer insulating film 200 may be located on the gate insulating film 150 to cover the gate electrode G of the transistor TR. The source electrode SDa and the drain electrode SDb of the transistor TR may be located on the interlayer insulating film 200.

The source electrode SDa and the drain electrode SDb may penetrate the interlayer insulating film 200 and the gate insulating film 150 and come into contact with the source region AS and the drain region AD of the transistor TR.

The planarization film 300 may be stacked on the interlayer insulating film 200 to cover the source electrode SDa and the drain electrode SDb of the transistor TR. The planarization film 300 may remove steps caused by the driving circuit, and may have a flat upper surface. The planarization film 300 may include an insulating material having high fluidity.

One of the source electrode SDa and the drain electrode SDb of the transistor TR may penetrate the planarization film 300 and come into contact a first electrode E1 of the light-emitting element OLED.

The bank 400 may be located on the planarization film 300. The bank 400 may define an emission area of each subpixel, and the areas of respective subpixels may be distinguished from each other by the bank 400.

The bank 400 may include a light-absorbing material, and may include, for example, a black pigment, such as carbon black. Accordingly, the bank 400 may absorb external light to reduce or minimize light reflectivity, further enhance black color, and improve a contrast ratio and color accuracy to further improve image quality.

The bank 400 may include an organic or an inorganic insulating material. As an example, the bank 400 may cover the edge of the first electrode E1 (e.g., an anode), without being limited thereto. As an example, the bank 400 may be in contact with a side surface of the edge of the first electrode E1, while not covering the edge of the first electrode E1, without being limited thereto. An emission layer EL and a second electrode E2 (e.g., a cathode) may be stacked on a portion of the first electrode E1 exposed by the bank 400.

Therefore, the respective emission areas of the plurality of subpixels SPB, SPR, and SPG may be distinguished by the bank 400. As an example, the emission area of each of the plurality of subpixels SPB, SPR, and SPG may be an area where the first electrode E1 is exposed by the bank 400. The light-emitting element OLED may be located in the emission area, and the light-emitting element OLED may include the first electrode E1, the emission layer EL, and the second electrode E2. As an example, the bank 400 may be located to overlap with spaces between first, second, and third lenses LB, LR, and LG, without being limited thereto.

The first electrode E1 may, for example, function as an anode and include a conductive material. As an example, the first electrode E1 may have high reflectivity, without being limited thereto. For example, the first electrode E1 may include a metal, such as aluminum (Al) or silver (Ag). The first electrode E1 may be exposed to the emission area of each subpixel by the bank 400.

The emission layer EL may generate light having a color with a brightness corresponding to a voltage difference between the first electrode E1 and the second electrode E2. For example, the emission layer EL provided in the first subpixel SPB may generate blue light, which is light having the first color, the emission layer EL provided in the second subpixel SPR may generate red light, which is light having the second color, and the emission layer EL provided in the third subpixel SPG may generate green light, which is light having the third color.

For this purpose, the emission layer EL may include an emission material layer EML including a light-emitting material. The light-emitting material may include an organic material, an inorganic material, or a hybrid material. For example, the emission layer EL may include the emission material layer EML formed of an organic material.

The emission layer EL may include at least one of a first light-emitting common layer (not shown) located between the emission material layer EML and the first electrode E1 or a second light-emitting common layer (not shown) located between the emission material layer EML and the second electrode E2. Each of the first light-emitting common layer (not shown) and the second light-emitting common layer (not shown) may include at least one of a hole transport layer HTL or an electron transport layer ETL. Embodiments are not limited thereto. As an example, the first light-emitting common layer or the second light-emitting common layer may be omitted depending on the design.

The emission layer EL may be conductively connected to the first, second, and third subpixels SPB, SPR, and SPG. For example, the emission material layer EML of each subpixel may be provided for each subpixel, but the first and second light-emitting common layers (not shown) may be commonly connected to the first, second, and third subpixels SPB, SPR, and SPG. Embodiments are not limited thereto. As an example, any one of the emission material layer EML and the first and second light-emitting common layers may be provided for each subpixel or may be commonly connected to the first, second, and third subpixels SPB, SPR, and SPG.

Accordingly, as an example, the emission layer EL of the first light-emitting element OLED provided in the first subpixel SPB and the emission layer EL of the second light-emitting element OLED provided in the second subpixel SPR may be conductively connected to each other.

The second electrode E2 may, for example, function as a cathode and include a conductive material. As an example, the second electrode E2 may include a different material from the first electrode E1, or include the same material as the first electrode E1. For example, the second electrode E2 may be a transparent electrode formed of a transparent conductive material, such as ITO or IZO. As an example, the second electrode E2 may have a higher transmittance than the first electrode E1, without being limited thereto.

The encapsulation layer 500 may be disposed on the second electrode E2 on the emission layer EL and perform an encapsulation function of reduce or preventing damage to the light-emitting elements OLED due to external impact and moisture.

As an example, the encapsulation layer 500 may be formed by a single layer or multiple layers. As an example, the encapsulation layer 500 may be formed by alternately stacking inorganic insulating material layers and organic insulating material layers. Steps caused by the light-emitting elements OLED may be removed by the encapsulation layer 500. As an example, the upper surface of the encapsulation layer 500 may be flat, without being limited thereto.

The optical layer 600 may be disposed on the encapsulation layer 500. The optical layer 600 may form an upper surface to function as an optical gap that induces uniform light refraction, thereby being capable of improving light extraction efficiency. For this purpose, the optical layer 600 may have a lower refractive index than the lenses LB, LR, and LG, and the thickness T600 of the optical layer 600 may be smaller than the maximum height H1 of each of the first, second, and third lenses LB, LR, and LG. The optical layer 600 may include a polyimide-acrylic composite (PAC).

The first barrier BR1 may be located between the encapsulation layer 500 and the optical layer 600. As an example, the first barrier BR1 may overlap with the bank 400. The first barrier BR1 may perform a function of reducing or preventing color mixing due to light having different colors emitted from the light-emitting elements OLED of adjacent subpixels. For example, the first barrier BR1 may be formed of a black matrix including a black pigment, which is a light-absorbing material, without being limited thereto.

The second barrier BR2 may be located on the optical layer 600. As an example, the second barrier BR2 may be located between the optical layer 600 and the low refractive index film 700, without being limited thereto. As an example, the second barrier BR2 may overlap with the bank 400 or the first barrier BR1. As an example, the edge of the second barrier BR2 may overlap with the edge of each of the first, second, and third lenses LB, LR, and LG, without being limited thereto.

The second barrier BR2 may perform a function of reducing or preventing color mixing due to the light having different colors emitted from the light-emitting elements OLED of the adjacent subpixels together with the first barrier BR1. As an example, the second barrier BR2 may be used as touch electrodes. As an example, the second barrier BR2 may be used as touch electrodes formed of an opaque metallic material, without being limited thereto. As an example, the second barrier BR2 may be used as touch driving electrodes or touch receiving electrodes. Embodiments are not limited thereto. As an example, the second barrier BR2 may be connected to the touch electrodes. As an example, the second barrier BR2 may be provided separately from the touch electrodes. As an example, the second barrier BR2 may be disconnected from the touch electrodes. As an example, the second barrier BR2 may be provided while no touch electrode is provided.

As described above, the first and second barriers BR1 and BR2 may reduce or prevent the colors of light from adjacent subpixels from being unnecessarily mixed and collected by the lenses of the corresponding subpixels, and may limit a viewing angle. As an example, the first and second barriers BR1 and BR2 may limit the viewing angle so that light having a color emitted from each subpixel does not interfere with the driver's view, without being limited thereto.

The plurality of lenses LB, LR, and LG may be located in a portion overlapping with the emission area of each subpixel on the optical layer 600. For example, one first lens LB may be disposed on the emission area of the first subpixel SPB to overlap with the emission area, one second lens LR may be disposed on the emission area of the second subpixel SPR to overlap with the emission area, and one third lens LG may be located on the emission area of the third subpixel SPG to overlap with the emission area. As an example, each of the plurality of lenses LB, LR, and LG may have a greater size than that of the emission area of the corresponding subpixel, without being limited thereto. As an example, the each of the plurality of lenses LB, LR, and LG may overlap with edge of the second barrier BR2, while exposing at least a center portion of the second barrier BR2, without being limited thereto. As an example, the plurality of lenses LB, LR, and LG may be spaced apart from each other on the top surface of the second barrier BR2, without being limited thereto.

As an example, each of the first, second, and third lenses LB, LR, and LG may have a refractive index greater than that of the low refractive index film 700, and may collect and emit light having a color emitted from a corresponding one of the first, second, and third subpixels SPB, SPR, and SPG, thereby being capable of improving the front brightness of the display panel.

As an example, each of the first, second, and third lenses LB, LR, and LG may include a second color reduction color filter pigment P1. The second color reduction color filter pigment P1 may include, for example, at least one of diketopyrrolopyrrole (DPP; PR254), quinacridone (PR122 and PR202), or perylene red (PR149), which is a pigment for red color filters, without being limited thereto. Embodiments are not limited thereto. As an example, the second lens LR may include the second color reduction color filter pigment P1, while at least one or each of the first lens LB and the third lenses LG may not include the second color reduction color filter pigment P1, without being limited thereto. As an example, the amount of the second color reduction color filter pigment P1 included in each of the first, second, and third lenses LB, LR, and LG may be the same or may be different from each other.

As an example, each of the first, second, and third lenses LB, LR, and LG may further include a binding polymer for color filters, and a dispersion stabilizer that assists uniform dispersion of pigment particles and film formation, in addition to the second color reduction color filter pigment P1, without being limited thereto.

As an example, the binding polymer for color filters may include at least one of epoxy resins, such as cycloaliphatic epoxy resin and Novolac epoxy resin, acrylic resins, such as poly(methyl methacrylate) and cross-linked acrylic polymers, polyimides, such as fluorinated polyimides, or polyurethanes, such as thermosetting polyurethanes, without being limited thereto.

As an example, the dispersion stabilizer that assists uniform dispersion of pigment particles and film formation may include at least one of hyperdispersants, polyvinyl pyrrolidone, silicone-based surfactants, or other additives, such as UV stabilizers or cross-linking agents, without being limited thereto.

As an example, each of the plurality of lenses LB, LR, and LG may be provided by mixing the second color reduction color filter pigment P1, the binding polymer, the dispersion stabilizer, and a polymer configured to form the lenses LB, LR, and LG, without being limited thereto.

As an example, the amount of reduction in the luminance of the second color light (R) by the second color reduction color filter pigment P1 may be greater than the amount of reduction in the luminance of the first color light (B) or the third color light (G) by the second color reduction color filter pigment P1. For example, the second color reduction color filter pigment P1 may absorb some of red light, which is the second color light (R) emitted from the second subpixel SPR, to reduce the luminance of the second color light (R), but the second color reduction color filter pigment P1 may maintain the luminance of the first color light (B) or the third color light (G) passing through the second color reduction color filter pigment P1 without reducing the luminance.

As an example, the second color reduction color filter pigment P1 may be included in a range of 0.01 wt % to 1 wt % with respect to the total weight of materials for forming each lens, in order to appropriately reduce the luminance of the second color light (R), without being limited thereto.

The transmittance (T) of the second color light (R) whose luminance is reduced may be defined as the following Equation 1 using the Lambert-Beer law.

$$T = 1 {0}^{- ε \cdot C \cdot l} \qquad [ Equation 1 ]$$

In Equation 1, T indicates the transmittance, & (L/mol cm) indicates the molar absorption coefficient of the second color reduction color filter pigment P1, C (wt %) is the concentration of the second color reduction color filter pigment P1, and 1 (cm) means an optical path length.

If the absorption coefficient of the second color reduction color filter pigment P1 and a film thickness are determined, the concentration C of the pigment P1 may be designed through reverse calculation by following Equation 2, considering the absorbance and transmittance of the light.

$$C = \frac{- log ( T )}{ε \cdot l} \qquad [ Equation 2 ]$$

The present disclosure may adjust the content of the second color reduction color filter pigment P1 within the above-mentioned range, so that the luminance of the second color light (R) may be set to be reduced by 1% to 10% by the second color reduction color filter pigment P1.

This will be described later after explaining the remaining components of the display panel 10.

The low refractive index film 700 may be located on the first, second, and third lenses LB, LR, and LG, and the second barrier BR2 exposed between the respective lenses LB, LR, and LG. The refractive index of the low refractive index film 700 may be smaller than the refractive index of each lens LB, LR, or LG.

The low refractive index film 700 may remove steps caused by the respective lenses LB, LR, and LG and have a flat upper surface. As an example, the low refractive index film 700 may include an insulating material having high fluidity, without being limited thereto. The thickness T700 of the low refractive index film 700 may be greater than the maximum height H1 of each of the first, second, and third lenses LB, LR, and LG.

As an example, the quarter wave plate QWP may be disposed on a low refractive index film 700 and phase-delay the wavelength of light having a color emitted from each subpixel passing through the first, second, or third lens LB, LR, or LG by ¼ wavelength (λ). The quarter wave plate QWP may convert linear polarization into circular polarization, and convert circular polarization into linear polarization. The quarter wave plate QWP may be provided together with a polarizing plate (not shown) to reduce reflection of external light or to increase or decrease the viewing angle of light having a color emitted from each subpixel. As an example, the quarter wave plate QWP may be omitted depending on the design.

A cover layer (not shown), such as glass, may be further provided on the quarter wave plate QWP to protect the quarter wave plate QWP from the outside.

The display panel of the present disclosure shown in FIG. 3 may, when an unwanted subpixel emits light due to lateral leakage current at low gray levels, reduce the light having a color emitted from the corresponding subpixel, thereby being capable of reducing or minimizing color defects of the display panel.

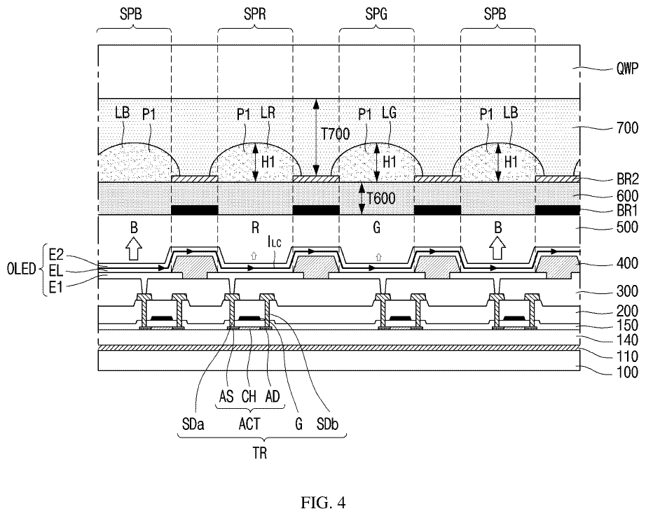

The effects of the present disclosure will be described with reference to FIGS. 4 to 9.

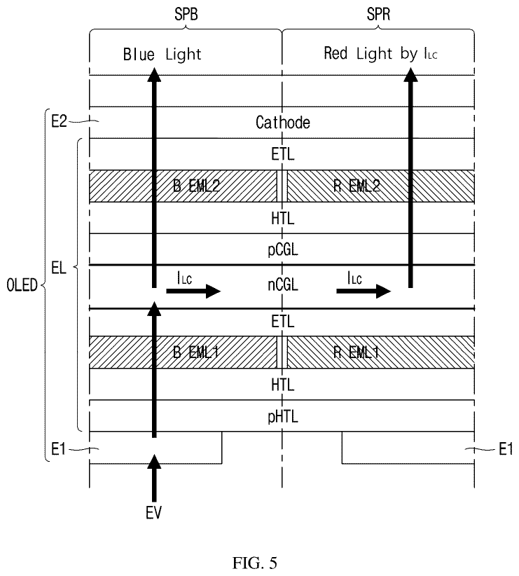

FIG. 4 is a cross-sectional view illustrating the flow of a lateral leakage current through the emission layer in the display panel shown in FIG. 3, and FIG. 5 is a cross-sectional view illustrating an example of the detailed cross-sections of the first and second light-emitting elements shown in FIG. 3 to explain the flow of the lateral leakage current through the emission layer in more detail.

As shown in FIGS. 4 and 5, as an example, the emission layer EL provided in each of the first and second light-emitting elements OLED of the first and second subpixels SPB and SPR may have, for example, a 2-stack structure, without being limited thereto.

For example, a p-type hole transport layer pHTL may be disposed on the first electrode E1 provided in each of the light-emitting elements OLED of the first and second subpixels SPB and SPR, and first and second stacks including first and second emission material layers may be disposed on the p-type hole transport layer pHTL.

The first and second emission material layers B EML1 and B EML2 of the first subpixel SPB may emit blue (B) light, and the first and second emission material layers R EML1 and R EML2 of the second subpixel SPR may emit red (R) light.

The first stack of each of the first and second subpixels SPB and SPR may have the first emission material layer B EML1 or R EML1, an electron transport layer ETL on the upper surface of the first emission material layer B EML1 or R EML1, and a hole transport layer HTL on the lower surface of the first emission material layer B EML1 or R EML1, and the hole transport layer HTL of the first stack may be disposed on the p-type hole transport layer pHTL. Embodiments are not limited thereto. As an example, at least one of the electron transport layer ETL, the hole transport layer HTL and the p-type hole transport layer pHTL may be omitted depending on the design.

A Li-doped n-type charge generation layer nCGL may be located on the electron transport layer ETL of the first stack, a p-type charge generation layer pCGL may be located on the n-type charge generation layer nCGL, and the second stack may be disposed on the p-type charge generation layer pCGL.

The second stack of each of the first and second subpixels SPB and SPR may include the second emission material layer B EML2 or R EML2, an electron transport layer ETL on the upper surface of the second emission material layer B EML2 or R EML2, and a hole transport layer HTL on the lower surface of the second emission material layer B EML2 or R EML2. The hole transport layer HTL of the second stack may be disposed on the p-type charge generation layer pCGL, and the electron transport layer ETL of the second stack may be disposed under the second electrode E2 provided in each of the first and second light-emitting elements OLED of the first and second subpixels SPB and SPR.

Here, as an example, at least one of or all of the n-type charge generation layer nCGL, p-type charge generation layer pCGL, the electron transport layers ETL, the hole transport layers HTL, and the p-type hole transport layer pHTL except for the first and second emission material layers EML1 and EML2 of the first and second stacks may be common layers provided in common in the first and second subpixels SPB and SPR and the third subpixel SPG, which is not shown in FIG. 5.

Among the common layers of the first, second, and third subpixels SPB, SPR, and SPG, the n-type charge generation layer nCGL may be doped with lithium (Li).

In the display panel shown in FIG. 4, when the transistor TR of the first subpixel SPB is operated and an emission voltage EV is applied to the first electrode E1 of the first light-emitting element OLED by the driving current Id of the transistor TR provided in the first subpixel SPB so that the emission layer EL emits light having the first color (e.g., blue (B) light) with a first luminance, as shown in FIG. 5, a lateral leakage current I_{LC} that flows from the emitting layer EL of the first light-emitting element OLED to the emitting layer EL of the second light-emitting element OLED may occur, as shown in FIGS. 4 and 5. For example, as shown in FIG. 5, the lateral leakage current I_{LC} may flow through the n-type charge generation layer nCGL that is commonly provided in the first and second subpixels SPB and SPR.

The first and second emission material layers R EML1 and R EML2 of the second subpixel SPR that emits red (R) light may emit relatively bright light even with a relatively low current due to the characteristics of the emission material layer itself, compared to the emission material layers of the first subpixel SPB that emits blue (B) light or the emission material layers of the third subpixel SPG that emits green (G) light, thereby being capable of exhibiting high luminous efficacy.

Accordingly, the emission layer EL of the second light-emitting element OLED provided in the second subpixel SPR may emit the second color light (e.g., red (R)) with a second luminance lower than the first luminance due to the lateral leakage current I_{LC}.

If a lens is not provided in each subpixel, the second color light (R) due to the lateral leakage current may barely affect colors on the display panel. However, as shown in FIG. 3, if a lens is provided in each subpixel, the luminance of the second color light (R) due to the lateral leakage current may significantly affect colors on the display panel due to light collection by the lens.

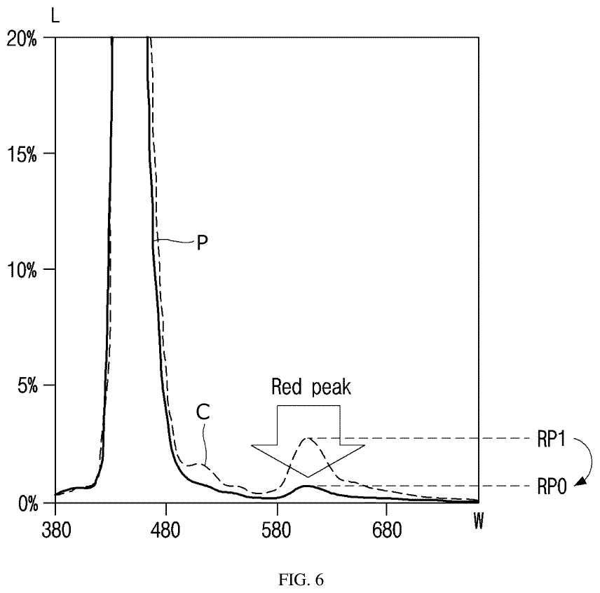

FIG. 6 is a diagram example illustrating optical spectral characteristics to explain the luminance of the second color light when the plurality of lenses shown in FIG. 3 does not include the second color reduction color filter pigment P1.

FIG. 6 illustrates an example of the optical spectrum measured when only the first subpixel SPB is turned on in a single unit pixel that includes the first, second, and third subpixels SPB, SPR and SPG. In FIG. 6, the x-axis represents the wavelength W of light, the y-axis may represent the luminance L of light, ‘P’ indicates an example of the present invention in which the plurality of lenses LB, LR, and LG includes the second color subtraction filter pigment P1, whereas ‘C’ indicates a comparative example in which the plurality of lenses LB, LR, and LG do not include the second color subtraction filter pigment P1.

As described above with reference to FIG. 3, when the first subpixel SPB is operated to emit light having the first color (B) with low-gray luminance while each subpixel has a lens that does not include the second color reduction color filter pigment P1, the second subpixel SPR may also emit light having the second color (R) with lower luminance than the first color light (B) due to the lateral leakage current I_{LC}.

Here, when the second lens LR of the second subpixel SPR does not include the second color reduction color filter pigment P1, the second color light (R) may be collected by the second lens LR, and the peak of the luminance of the second color light (R) may be excessively increased to RP1 of the comparative example C so that the second color (R) is visible.

However, as in the present disclosure, when the second lens LR of the second subpixel SPR includes the second color reduction color filter pigment P1, the second color reduction color filter pigment P1 may absorb a portion of the second color light (R), thereby reducing the peak of the luminance of the second color light (R) from RP1 to RP0 of the present invention P.

In this way, the present disclosure may reduce the luminance of the second color light (R) using the second color reduction color filter pigment P1. Here, the second color reduction color filter pigment P1 included in the first lens LB of the first subpixel SPB does not absorb the first color light (B) at all, and thus, the luminance of the first color light (B) may not be reduced.

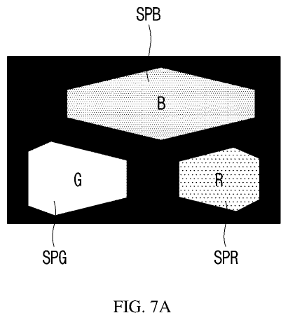

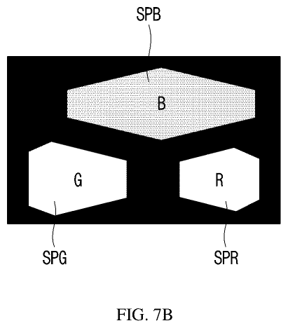

FIGS. 7A and 7B are diagrams comparatively illustrating light having a color emitted from each subpixel by comparing a case in which the plurality of lenses LB, LR, and LG does not include the second color reduction color filter pigment P1 and a case in which the plurality of lenses LB, LR, and LG includes the second color reduction color filter pigment P1.

FIG. 7A shows a comparative example in which the plurality of lenses LB, LR, and LG does not include the second color reduction color filter pigment P1, and illustrates the luminances of blue light, red light, and green light visible through the lenses of the first, second, and third subpixels SPB, SPR, and SPG when a low-gray-level emission voltage EV is applied to the first subpixel SPB, and FIG. 7B shows the present disclosure in which the plurality of lenses LB, LR, and LG includes the second color reduction color filter pigment P1, and illustrates the luminances of blue light, red light, and green light visible through the lenses of the first, second, and third subpixels SPB, SPR, and SPG when a low-gray-level emission voltage EV is applied to the first subpixel SPB.

As illustrated in FIG. 7A, in the case of the comparative example in which the plurality of lenses LB, LR, and LG does not include the second color reduction color filter pigment P1, as described above in FIGS. 4 to 6, it may be confirmed that, when the low-gray-level emission voltage EV is applied to the first subpixel SPB depending on the driving current Id of the transistor TR, the first color light (B) from the first subpixel SPB is visible, and the second color light (R) from the second subpixel SPR is also visible due to the lateral leakage current I_{LC}.

However, in the case of the present disclosure, as shown in FIG. 7B, it may be confirmed that the second color light (R) from the second subpixel SPR due to the lateral leakage current (I_{LC}) is not visible because the second color light (R) is reduced by the second color reduction color filter pigment P1, and only the first color light (B) from the first subpixel SPB is visible.

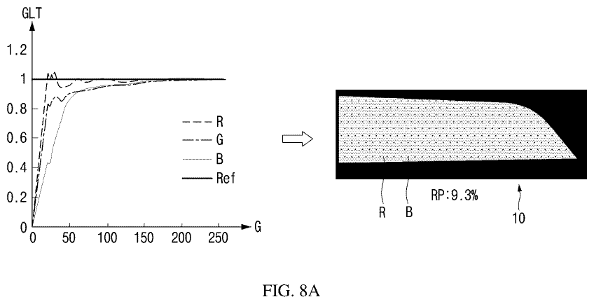

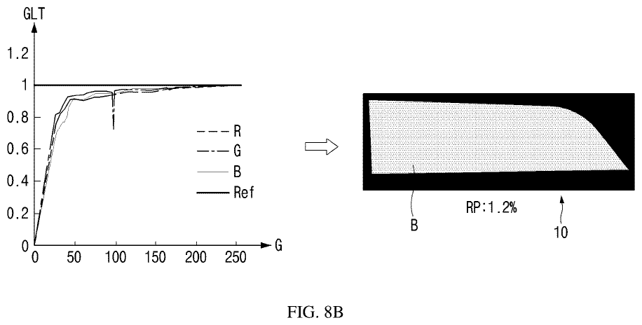

FIGS. 8A and 8B are diagrams illustrating luminous efficacies of the first, second, and third subpixels and colors of a display screen in the case in which the plurality of lenses does not include the second color reduction color filter pigment and the case in which the plurality of lenses includes the second color reduction color filter pigment.

FIG. 8A shows a gray level lifetime (GLT) graph for explaining the luminous efficacies of the subpixels LB, LR, and LG when the plurality of subpixels LB, LR, and LG does not include the second color reduction color filter pigment P1 according to the comparative example, and colors displayed on the screen, i.e., Front of Screen (FOS), of the display panel 10 when a driving current Id is applied to the first subpixel SPB while the plurality of lenses LB, LR, and LG does not include the second color reduction color filter pigment P1.

FIG. 8B shows a gray level lifetime (GLT) graph for explaining the luminous efficacies of the subpixels LB, LR, and LG when the plurality of subpixels LB, LR, and LG includes the second color reduction color filter pigment P1 according to the one exemplary embodiment of the present disclosure, and colors displayed on the screen, i.e., Front of Screen (FOS), of the display panel 10 when a driving current Id is applied to the first subpixel SPB while the plurality of lenses LB, LR, and LG includes the second color reduction color filter pigment P1.

The luminous efficacy of a subpixel may be calculated as the ratio of luminance L of output light having a color to the driving current Id applied to the emission layer EL of the subpixel, and the luminous efficacy may increase as the magnitude of the driving current Id applied to implement the same luminance (L) of the light decreases.

If the magnitude of the driving current Id applied to ensure that the subpixel has the same luminance L of the light is relatively large, deterioration of the subpixel may occur relatively significantly, and the lifespan of the subpixel may decrease relatively quickly. This case may mean that the luminous efficacy of the subpixel is relatively low.

In addition, if the magnitude of the driving current Id applied to ensure that the subpixel has the same luminance L of the light is relatively small, deterioration of the subpixel may occur relatively little, and the lifespan of the subpixel may increase relatively. This case may mean that the luminous efficacy of the subpixel is relatively high.

In this way, the luminous efficacy of the subpixel may be explained by a graph of the lifespan of the subpixel.

The graphs shown in FIGS. 8A and 8B are showing the lifetime of each subpixel depending on the gray level, and in the graphs, the x-axis represents the gray level G, and the y-axis represents the gray level lifetime GLT of each subpixel depending on the gray level.

In the state in which the plurality of lenses LB, LR, and LG does not include the second color reduction color filter pigment P1, as in the graph of FIG. 8A, when the gray level (G) of light having the colors is high, for example, 50 or higher, it may be confirmed that the lifetimes GLT of the first, second, and third subpixels SPB, SPR, and SPG are all below a reference value Ref, and thus the luminous efficacies of the first, second, and third subpixels SPB, SPR, and SPG have similar forms. However, for example, at low gray levels where the gray level G of light having the colors is 50 or lower, it may be confirmed that the lifetime GLT of the second subpixel SPR is above the reference value Ref. Therefore, it may be confirmed that the luminous efficacy of the second subpixel SPR is higher than those of the first and third subpixels SPB and SPG at low gray levels.

Due to the high luminous efficacy of the second subpixel SPR at low gray levels, when the driving current Id is applied to the first subpixel SPB in the state in which the plurality of lenses LB, LR, and LG does not include the second color reduction color filter pigment P1, the second subpixel SPR may easily emit the second color light (R) on the screen (FOS) of the display panel 10 due to the lateral leakage current I_{LC}.

In this case, the peak RP of the luminance of the second color light (R) may reach, for example, 9.3% of the luminance of the first color light (B). Accordingly, not only the first color (B) but also the second color (R) may be visible on the screen of the display panel 10 shown in FIG. 8A, and accordingly, it may be confirmed that color defects occur on the display screen.

However, as in the present disclosure, in the case in which the plurality of lenses LB, LR, and LG includes the second color reduction color filter pigment P1, as in the graph of FIG. 8B, it may be confirmed that the lifetime GLT of the second subpixel SPR is below the reference value Ref even at low gray levels, and thus the luminous efficacy of the second subpixel SPR is similar to the luminous efficacies of the first and third subpixels SPB and SPG. As an example, the difference between the luminous efficacy at low gray levels of the second subpixel SPR and the luminous efficacies of the first and third subpixels SPB and SPG are reduced by the second color reduction color filter pigment P1.

In this way, the present disclosure may allow the plurality of lenses LB, LR, and LG to include the second color reduction color filter pigment P1, thereby being capable of reducing the luminous efficacy of the second subpixel SPR at low gray levels, as in the graph of FIG. 8B,

Thereby, the peak RP of the luminance of the second color light (R) due to the lateral leakage current I_{LC} when the driving current Id is applied to the first subpixel SPB may be significantly reduced. As an example, the peak RP of the luminance of the second color light (R) due to the lateral leakage current I_{LC} when the driving current Id is applied to the first subpixel SPB may be significantly reduced such that the second color light (R) is not visible, on the screen (FOS) of the display panel 10. As an example, the peak RP of the luminance of the second color light (R) due to the lateral leakage current I_{LC} when the driving current Id is applied to the first subpixel SPB may be significantly reduced to, for example, 1.2% or less, without being limited thereto.

Therefore, the first color light (B) is visible, but the second color light (R) is not visible, on the screen (FOS) of the display panel 10 shown in FIG. 8B. Accordingly, the present disclosure may reduce or minimize color defects that may occur at low gray levels if each subpixel is provided with a lens.

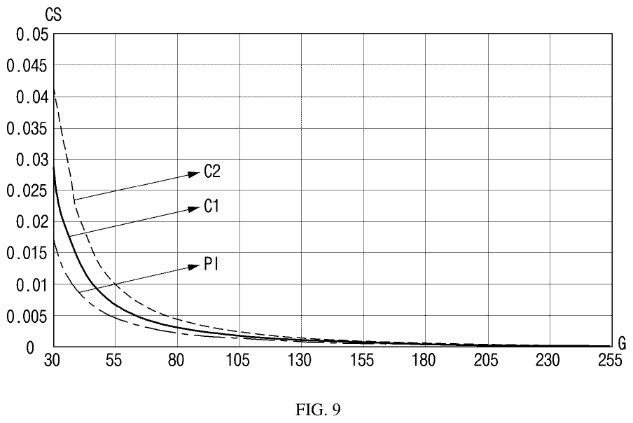

FIG. 9 is a simulation graph illustrating color differences of the display panel according to an exemplary embodiment of the present disclosure.

In FIG. 9, the x-axis may represent a gray level G, and the y-axis may represent a difference value (i.e., a color shift (CS) value) of color coordinates, (Δx′ y′). Increase in the color shift (CS) value of the color coordinates may indicate increase in a color difference.

C1 may indicate color coordinates of a first comparative example in which a lens is not provided on each subpixel, C2 may indicate color coordinates of a second comparative example in which a lens is provided on each subpixel but the lens does not include the second color reduction color filter pigment P1, and P1 may indicate color coordinates of the present disclosure in which the plurality of lenses LB, LR, and LG includes the second color reduction color filter pigment P1.

As shown in FIG. 9, in all the first and second comparative examples C1 and C2 and the present disclosure P1, it may be confirmed that, as the gray level G increases, the color shift (CS) value of the color coordinates decreases so that there is almost no color difference. However, it may be confirmed that, as the gray level G decreases, the color shift (CS) value of the color coordinates increases so that a color difference occurs.

However, it may be confirmed that the color shift (CS) value of the color coordinates in the case of the present disclosure P1 is lower than that of the first comparative example C1 or the second comparative example C2 even at low gray levels G. Accordingly, in the case of the present disclosure P1 in which the plurality of lenses LB, LR, and LG includes the second color reduction color filter pigment P1, it may be confirmed that the color difference is reduced at low gray levels compared to the first comparative example C1 or the second comparative example C2.

Although it is described that the display devices are used in vehicles, the embodiments of the present disclosure are not limited thereto. As an example, the display devices of the present disclosure may be applied to any devices such as a computer, a TV, a laptop, a mobile phone, an e-book reader, a tablet, a building, a household appliance, etc.

In this way, one exemplary embodiment of the present disclosure may allow the first lens located on the first subpixel emitting light having the first color and the second lens located on the second subpixel emitting light having the second color to include the second color reduction color filter pigment that reduces the luminance of the second color light, so that, when the first light-emitting element is driven to emit low-gray-level light having the first color, even if the second light-emitting element emits the second color light due to the lateral leakage current of the first light-emitting element, the luminance of the second color light is reduced, thereby being capable of improving a low-gray-level color defect of the display panel.

As is apparent from the above description, one exemplary embodiment of the present disclosure may allow a first lens located on a first subpixel configured to emit a first color light and a second lens located on a second subpixel configured to emit a second color light to include a second color reduction color filter pigment that reduces the luminance of the second color light, so that, when the first light-emitting element is driven to emit low-gray-level light having the first color, even if the second light-emitting element emits the second color light due to the lateral leakage current of the first light-emitting element, the luminance of the second color light is reduced, thereby being capable of improving a low-gray-level color defect of a display panel.

Through the above description, it should be apparent to those skilled in the art that various changes and modifications are possible without departing from the technical spirit of the present disclosure. Therefore, the technical scope of the present disclosure should not be limited to the above detailed description, but should be defined by the scope of the claims.

What is claimed is:

1. A display panel comprising:
a first subpixel including a first light-emitting element configured to emit a first color light;
a second subpixel including a second light-emitting element configured to emit a second color light;
a first lens disposed on the first subpixel to overlap with the first subpixel; and
a second lens disposed on the second subpixel to overlap with the second subpixel,
wherein the second lens comprises a second color reduction color filter pigment configured to reduce a luminance of the second color light.

2. The display panel according to claim 1, wherein the first lens further comprises the second color reduction color filter pigment.

3. The display panel according to claim 2, wherein an amount of reduction in the luminance of the second color light by the second color reduction color filter pigment is greater than an amount of reduction in a luminance of the first color light by the second color reduction color filter pigment.

4. The display panel according to claim 2, wherein each of the first and the second light-emitting elements comprises a first electrode conductively connected to a driving transistor in each of the first and the second subpixels, an emission layer disposed on the first electrode, and a second electrode disposed on the emission layer,
wherein the emission layer of the first light-emitting element and the emission layer of the second light-emitting element are conductively connected to each other.

5. The display panel according to claim 4, wherein:
an emission voltage is applied to the first electrode of the first light-emitting element,
the emission layer of the first light-emitting element emits the first color light with a first luminance, and
the emission layer of the second light-emitting element emits the second color light with a second luminance, wherein the second luminance is lower than the first luminance due to a lateral leakage current flowing through the emission layer of the second light-emitting element.

6. The display panel according to claim 5, wherein the first luminance of the first color light passing through the second color reduction color filter pigment in the first lens is maintained same, and the second luminance of the second color light is reduced by the second color reduction color filter pigment in the second lens.

7. The display panel according to claim 6, wherein the second luminance of the second color light is set to be reduced by 1% to 10% by the second color reduction color filter pigment in the second lens due to the lateral leakage current.

8. The display panel according to claim 5, wherein a peak of the second luminance of the second color light is reduced to 1.2% or less of a peak of the first luminance of the first color light due to the lateral leakage current.

9. The display panel according to claim 5, wherein the lateral leakage current flows from the emitting layer of the first light-emitting element to the emitting layer of the second light-emitting element through an n-type charge generation layer of the emission layer.

10. The display panel according to claim 1, wherein the first color light is green light or blue light, and the second color light is red light.

11. The display panel according to claim 1, wherein a luminous efficacy of the second light-emitting element is higher than a luminous efficacy of the first light-emitting element at low gray levels.

12. The display panel according to claim 1, wherein the second color reduction color filter pigment comprises at least one pigment for red color filters selected from diketopyrrolopyrrole (DPP), quinacridone, and perylene red.

13. The display panel according to claim 2, wherein the first lens and the second lens comprise the second color reduction color filter pigment in a range of 0.01 wt % to 1 wt %.

14. The display panel according to claim 1, wherein:
a number of the first lens disposed on the first light-emitting element is one; and
a number of the second lens disposed on the second light-emitting element is one.

15. The display panel according to claim 1, further comprising:
a low refractive index film disposed on the first lens and the second lens,
wherein a refractive index of the first lens and the second lens is greater than a refractive index of the low refractive index film.

16. The display panel according to claim 15, further comprising:
an encapsulation layer disposed on the first light-emitting element and the second light-emitting element; and
an optical layer disposed between the encapsulation layer and the first lens and the second lens,
wherein a thickness of the optical layer is less than a maximum height of each of the first lens and the second lens.

17. The display panel according to claim 15, wherein a thickness of the low refractive index film is greater than a maximum height of each of the first lens and the second lens.

18. The display panel according to claim 15, further comprising:
an encapsulation layer disposed on the first light-emitting element and the second light-emitting element;
an optical layer disposed between the encapsulation layer and the first lens and the second lens; and
a bank configured to define an emission area of the first subpixel and an emission area of the second subpixel,
wherein the bank overlaps with a space between the first lens and the second lens.

19. The display panel according to claim 18, further comprising a first barrier positioned between the encapsulation layer and the optical layer,
wherein the first barrier overlaps with the bank, and
wherein the first barrier is a black matrix comprising a light-absorbing material.

20. The display panel according to claim 18, further comprising a second barrier between the optical layer and the low refractive index film, wherein the second barrier overlaps with the bank.

21. The display panel according to claim 20, wherein the second barrier is used as touch electrodes, or wherein the second barrier is connected to the touch electrodes, and wherein the second barrier is formed of an opaque conductive material.

22. The display panel according to claim 20, wherein an edge of the second barrier overlaps with an edge of the first lens and an edge of the second lens.

23. The display panel according to claim 22, wherein the first lens and the second lens are spaced apart from each other on a top surface of the second barrier.

24. The display panel according to claim 2, wherein each of the first lens and the second lens further comprises a binding polymer and a dispersion stabilizer.

25. The display panel according to claim 3, further comprising:
a third subpixel having a third light-emitting element configured to emit a third color light; and
a third lens disposed on the first subpixel to overlap with the first subpixel,
wherein the third lens further comprises the second color reduction color filter pigment, and
wherein an amount of reduction in the luminance of the second color light by the second color reduction color filter pigment is greater than an amount of reduction in a luminance of the third color light by the second color reduction color filter pigment.

26. A vehicle, comprising the display panel according to claim 1.
